(19) United States
(12) Patent Application Publication
(10) Pub. No.: US 2025/0092565 A1
(43) Pub. Date: Mar. 20, 2025

(54) GROUP III NITRIDE CRYSTAL MANUFACTURING APPARATUS AND MANUFACTURING METHOD

(71) Applicant: Panasonic Holdings Corporation, Osaka (JP)

(72) Inventors: JUNICHI TAKINO, Osaka (JP); MASAYUKI HOTEIDA, Osaka (JP); SHUNICHI MATSUNO, Kyoto (JP)

(21) Appl. No.: 18/961,659

(22) Filed: Nov. 27, 2024

Related U.S. Application Data
(63) Continuation of application No. PCT/JP2023/016128, filed on Apr. 24, 2023.

(30) Foreign Application Priority Data
Jun. 9, 2022 (JP) 2022-093955

(51) Int. Cl. C30B 25/14; C30B 25/08; C30B 29/40

(52) U.S. Cl. CPC C30B 25/14; C30B 25/08; C30B 29/406

(57) ABSTRACT

A group III nitride crystal manufacturing apparatus includes a raw material chamber that generates a group III element oxide gas, a growth chamber that causes the group III element oxide gas supplied from the raw material chamber to react with a nitrogen element-containing gas to generate a group III nitride crystal on a seed substrate, a first exhaust pipe connected downstream of the growth chamber that discharges gas from the growth chamber and is set to more than or equal to 1000° C., a first deposition pipe connected to a downstream side of the first exhaust pipe and set to more than or equal to 700° C. and less than 1050° C., a second deposition pipe connected to a downstream side of the first deposition pipe and set to less than 800° C., and a second exhaust pipe connected to a downstream side of the second deposition pipe that exhausts gas to an outside.

### TECHNICAL FIELD

The present disclosure relates to a group III nitride crystal manufacturing apparatus and manufacturing method.

### BACKGROUND ART

Group III nitride crystals such as GaN are expected to be applied to next-generation optical devices such as a high-output LED (light emitting diode) and an LD (laser diode), and next-generation electronic devices such as a high-output power transistor mounted on an EV (electric vehicle), a PHV (plug-in hybrid vehicle), and the like. As a method for producing a group III nitride crystal, an oxide vapor phase epitaxy (OVPE) method using a group III element oxide as a raw material is used (see, for example, PTL 1).

An example of the reaction system in the OVPE method is as follows. Ga is heated, and in this state, H₂O gas is introduced. The introduced H₂O gas reacts with Ga to generate Ga₂O gas (Formula (I)). Then, an NH₃ gas is introduced, and the NH₃ gas is caused to react with the generated Ga₂O gas to generate a GaN crystal on a seed substrate (Formula (II)).

2Ga(1)+H₂O(g)→Ga₂O(g)+H₂(g) (I)

Ga₂O(g)+2NH₃(g)→2GaN(s)+H₂O(g)+2H₂(g) (II)

### CITATION LIST

### Patent Literature

PTL 1: International Publication No. 2015/053341

### SUMMARY OF THE INVENTION

A group III nitride crystal manufacturing apparatus according to one aspect of the present disclosure includes a raw material chamber that generates a group III element oxide gas, a growth chamber that causes the group III element oxide gas supplied from the raw material chamber to react with a nitrogen element-containing gas to generate a group III nitride crystal on a seed substrate, a first exhaust pipe that is connected downstream of the growth chamber, discharges gas from the growth chamber, and is set to more than or equal to 1000° C., a first deposition pipe connected to a downstream side of the first exhaust pipe and set to more than or equal to 700° C. and less than or equal to 1050° C., a second deposition pipe connected to a downstream side of the first deposition pipe and set to less than 800° C., and a second exhaust pipe that is connected to a downstream side of the second deposition pipe and exhausts gas to an outside.

A method for producing a group III nitride crystal according to one aspect of the present disclosure includes causing a group III element source to react with a reactive gas to produce a group III element oxide gas, causing the group III element oxide gas to react with a nitrogen element-containing gas to generate a group III nitride crystal on a seed substrate, and causing a film-like deposit to deposit at a temperature of more than or equal to 700° C. and less than or equal to 1050° C. and then causing a powdery deposit to deposit at a temperature of less than 800° C. with respect to exhaust of unreacted group III element oxide gas of more than or equal to 1000° C. to be exhausted.

### BRIEF DESCRIPTION OF THE DRAWINGS

FIG. 1 is a schematic sectional view illustrating a sectional structure of a group III nitride crystal manufacturing apparatus according to a first exemplary embodiment of the present disclosure.

FIG. 2 is a flowchart of a method for producing a group III nitride crystal according to the first exemplary embodiment of the present disclosure.

FIG. 3 is a schematic sectional view illustrating a sectional structure of a group III nitride crystal manufacturing apparatus according to a second exemplary embodiment of the present disclosure.

FIG. 4 is a flowchart of a method for producing a group III nitride crystal according to the second exemplary embodiment of the present disclosure.

### DESCRIPTION OF EMBODIMENT

In the production method described in PTL 1, when a group III nitride crystal is grown, an unreacted group III element oxide gas, an oxide gas of a reaction by-product, and an unreacted oxide gas react with each other in an exhaust pipe in a downstream portion of the group III nitride crystal, and a solid of a group III element oxide deposits on the exhaust pipe. The reaction formula when the group III element is Ga and the oxide gas is H₂O gas is shown in Formula (III). The group III element oxide gas changes into a solid in a low temperature region. For example, when the group III element is Ga, the change of Formula (IV) occurs, and the solidified group III element oxide gas deposits on the exhaust pipe.

Ga₂O(g)+2H₂O(g)=Ga₂O₃(s)+2H₂(g) (III)

Ga₂O(g)=Ga₂O(s) (IV)

The deposition of these solids causes clogging of the exhaust pipe and disturbs continuous operation of the group III nitride crystal production.

The present disclosure has been made to solve the above problems, and an object of the present disclosure is to provide a group III nitride crystal manufacturing apparatus and a manufacturing method capable of producing a high-quality group III nitride crystal by suppressing deposition of a group III element oxide solid on an exhaust pipe.

A group III nitride crystal manufacturing apparatus according to a first aspect includes a raw material chamber that generates a group III element oxide gas, a growth chamber that causes the group III element oxide gas supplied from the raw material chamber to react with a nitrogen element-containing gas to generate a group III nitride crystal on a seed substrate, a first exhaust pipe that is connected downstream of the growth chamber, discharges gas from the growth chamber, and is set to more than or equal to 1000° C., a first deposition pipe connected to a downstream side of the first exhaust pipe and set to more than or equal to 700° C. and less than or equal to 1050° C., a second deposition pipe connected to a downstream side of the first deposition pipe and set to less than 800° C., and a second exhaust pipe that is connected to a downstream side of the second deposition pipe and exhausts gas to an outside.

A group III nitride crystal manufacturing apparatus according a second aspect, in the first aspect, may have a temperature set to decrease in an order of the first exhaust pipe, the first deposition pipe, and the second deposition pipe.

A group III nitride crystal manufacturing apparatus according to a third aspect, in the first or second aspect, may include a protective pipe provided on an inner wall of the first deposition pipe.

In a group III nitride crystal manufacturing apparatus according a fourth aspect, in the third aspect, the protective pipe may contain at least one material selected from the group consisting of pyrolytic graphite (PG), pyrolytic boron nitride (PBN), carbon (C), silicon carbide (SiC), transition metal, and quartz.

In a group III nitride crystal manufacturing apparatus according to a fifth aspect, in the third or fourth aspect, the protective pipe may have an inner diameter of more than or equal to 66 mm.

In a group III nitride crystal manufacturing apparatus according a sixth aspect, in any one of the first to fifth aspect, the second deposition pipe may include a powder trap filter.

In a group III nitride crystal manufacturing apparatus according to a seventh aspect, in the sixth aspect, the powder trap filter may have a filter roughness of less than or equal to 100 μm.

A method for producing a group III nitride crystal according to an eighth aspect includes causing a group III element source to react with a reactive gas to produce a group III element oxide gas, causing the group III element oxide gas to react with a nitrogen element-containing gas to generate a group III nitride crystal on a seed substrate, and causing a film-like deposit to deposit at a temperature of more than or equal to 700° C. and less than or equal to 1050° C. and then causing a powdery deposit to deposit at a temperature of less than 800° C. with respect to exhaust of unreacted group III element oxide gas of more than or equal to 1000° C. to be exhausted.

In a method for producing a group III nitride crystal according to a ninth aspect, in the eighth aspect, the exhaust of the group III element oxide gas may be performed to an outside via a first exhaust pipe having a temperature of more than or equal to 1000° C., a first deposition pipe having a temperature of more than or equal to 700° C. and less than or equal to 1050° C., a second deposition pipe having a temperature of less than 800° C., and a second exhaust pipe.

In a method for producing a group III nitride crystal according to a tenth aspect, in the ninth aspect, a temperature may be caused to decrease in an order of the first exhaust pipe, the first deposition pipe, and the second deposition pipe.

A method for producing a group III nitride crystal according to an eleventh aspect, in the ninth or tenth aspect, may further include decomposing a part of the nitrogen element-containing gas that has not reacted between the seed substrate and the first exhaust pipe.

The group III nitride crystal manufacturing apparatus and manufacturing method according to an aspect of the present disclosure can suppress clogging of an exhaust pipe and produce a high-quality group III nitride crystal with high productivity.

### First Exemplary Embodiment

### <Outline of Group III Nitride Crystal Manufacturing Apparatus>

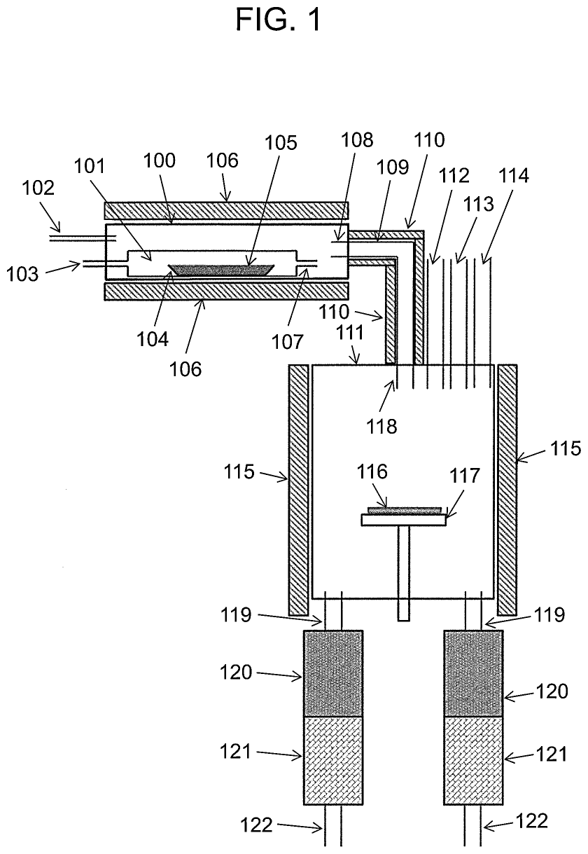

FIG. 1 is a schematic sectional view illustrating a sectional structure of a group III nitride crystal manufacturing apparatus according to a first exemplary embodiment of the present disclosure. The group III nitride crystal manufacturing apparatus according to the first exemplary embodiment will be described with reference to FIG. 1. FIG. 1 is a schematic view, and the size, ratio, and the like of each component may be different from the actual size, ratio, and the like.

The group III nitride crystal manufacturing apparatus according to the first exemplary embodiment includes raw material chamber 100. Raw material reaction room 101 is disposed in raw material chamber 100, and raw material boat 104 on which starting group III element source 105 is placed is disposed in raw material reaction room 101. In the present exemplary embodiment, starting group III element source 105 is a starting Ga source. Raw material reaction room 101 is connected with reactive gas supply pipe 103 that supplies a reactive gas that reacts with starting group III element source 105. Raw material reaction room 101 includes group III element oxide gas discharge port 107. When starting group III element source 105 is an oxide, a reducing gas is used as the reactive gas. When starting group III element source 105 is a metal, an oxidizing gas is used as the reactive gas. Raw material chamber 100 is provided with first carrier gas supply port 102. A first carrier gas supplied from first carrier gas supply port 102 carries the group III element oxide gas discharged from group III element oxide gas discharge port 107, from gas discharge port 108 through connection pipe 109 to growth chamber 111. Growth chamber 111 includes gas supply port 118 that supplies the group III element oxide gas and the first carrier gas, third carrier gas supply port 112, nitrogen element-containing gas supply port 113, and second carrier gas supply port 114. The manufacturing apparatus further includes first exhaust pipe 119, first deposition pipe 120, second deposition pipe 121, and second exhaust pipe 122.

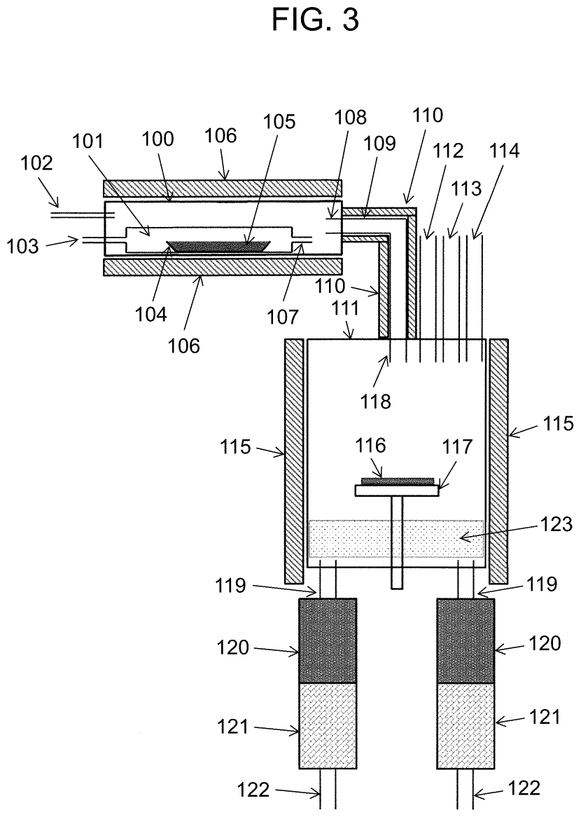

As illustrated in FIG. 3, decomposition accelerator 123 may be provided. Substrate susceptor 117 on which seed substrate 116 is placed is disposed in growth chamber 111.

The group III nitride crystal manufacturing apparatus of the present disclosure includes first deposition pipe 120 installed downstream of first exhaust pipe 119, second deposition pipe 121 installed downstream of first deposition pipe 120, and second exhaust pipe 122 installed further downstream of the second deposition pipe. First exhaust pipe 119 can cause the group III element oxide gas that has not reacted in the crystal growth process, an oxide gas that is a by-product at the time of the growth of the group III nitride crystal, and the oxide gas that has not reacted at the time of the generation of the group III element oxide gas to flow downstream. First deposition pipe 120 and second deposition pipe 121 receive these oxide gases, respectively, and generate a deposit, which can prevent clogging of the exhaust pipe. Thus, the group III nitride crystals can be continuously grown, and the production efficiency of the group III nitride crystals can improve. In addition, since damage and contamination of the exhaust pipe can be reduced, the maintenance cost can be suppressed, and the manufacturing cost of the group III nitride crystal can be reduced.

### <Outline of Method for Producing Group III Nitride Crystal>

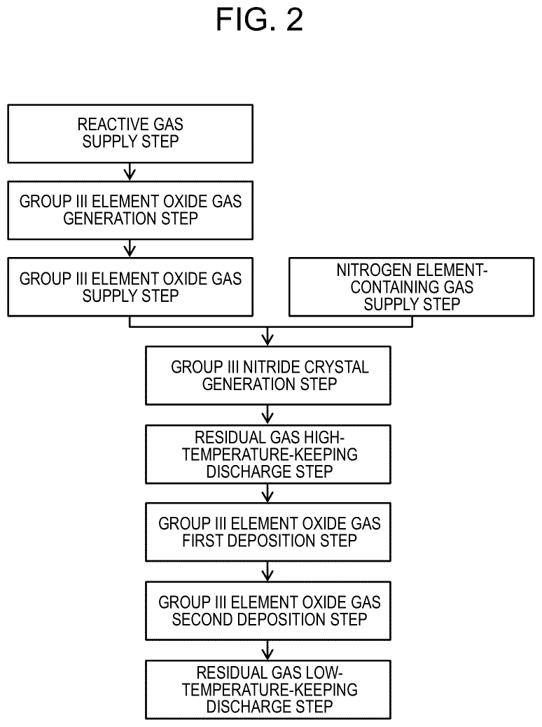

FIG. 2 is a flowchart of a method for producing a group III nitride crystal according to the first exemplary embodiment of the present disclosure. The method for producing a group III nitride crystal according to the first exemplary embodiment of the present disclosure will be described with reference to the flowchart of FIG. 2.

The method for producing a group III nitride crystal according to the first exemplary embodiment includes a reactive gas supply step, a group III element oxide gas generation step, a group III element oxide gas supply step, a nitrogen element-containing gas supply step, a group III nitride crystal generation step, a residual gas high-temperature-keeping discharge step, a group III element oxide gas deposition step, and a residual gas low-temperature-keeping discharge step.

### <Reactive Gas Supply Step>

In the reactive gas supply step, a reactive gas is supplied from reactive gas supply pipe 103 to raw material reaction room 101 in raw material chamber 100. As described above, as the reactive gas, a reducing gas or an oxidizing gas may be used as necessary.

### <Group III Element Oxide Gas Generation Step>

In the group III element oxide gas generation step, starting group III element source 105 is caused to react with the reactive gas (reducing gas when the starting group III element source is an oxide, oxidizing gas when the starting group III element source is a metal) in raw material reaction room 101 to generate a group III element oxide gas.

### <Group III Element Oxide Gas Supply Step>

In the group III element oxide gas supply step, the group III element oxide gas produced in the group III element oxide gas generation step is supplied to growth chamber 111. The group III element oxide gas is discharged from the inside of raw material reaction room 101 through group III element oxide gas discharge port 107, discharged from gas discharge port 108 together with the first carrier gas supplied from first carrier gas supply port 102, carried through connection pipe 109, and supplied from gas supply port 118 into growth chamber 111.

### <Nitrogen Element-Containing Gas Supply Step>

In the nitrogen element-containing gas supply step, a nitrogen element-containing gas is supplied from nitrogen element-containing gas supply port 113 to growth chamber 111.

### <Group III Nitride Crystal Generation Step>

In the group III nitride crystal generation step, the group III element oxide gas supplied into growth chamber 111 in the group III element oxide gas supply step and the nitrogen element-containing gas supplied into growth chamber 111 in the nitrogen element-containing gas supply step are caused to react to grow a group III nitride crystal on seed substrate 116.

### <Residual Gas High-Temperature-Keeping Discharge Step>

In the residual gas high-temperature-keeping discharge step, unreacted gas that does not contribute to the generation of the group III nitride crystals is discharged while a high temperature is kept to such an extent that the group III element oxide gas does not deposit.

### <Group III Element Oxide Gas First and Second Deposition Steps>

In the group III element oxide gas first and second deposition steps, a solid material of the group III element oxide gas is caused to deposit in the first deposition pipe and the second deposition pipe on the downstream side of the first exhaust pipe so as not block the exhaust pipe.

### <Residual Gas Low-Temperature-Keeping Discharge Step>

In the residual gas low-temperature-keeping discharge step, the exhaust gas other than the group III element oxide gas is discharged while the temperature is kept to be lower than the heat-resistant temperature of a seal member or the like installed at the pipe joint.

### <Details of Method and Apparatus for Producing Group III Nitride Crystal>

Details of the method for producing a group III nitride crystal according to the first exemplary embodiment will be described. In the present exemplary embodiment, metal Ga is used as starting group III element source 105.

### <Reactive Gas Supply Step>

In the reactive gas supply step, reactive gas is supplied from reactive gas supply pipe 103 to raw material reaction room 101. In the present exemplary embodiment, since metal Ga is used as starting group III element source 105, H₂O gas is used as the reactive gas. As the reactive gas, O₂ gas, CO gas, NO gas, N₂O gas, NO₂ gas, or N₂O₄ gas may be used.

### <Group III Element Oxide Gas Generation Step>

In the group III element oxide gas generation step, the reactive gas supplied to raw material reaction room 101 in the reactive gas supply step reacts with Ga as starting group III element source 105 to generate Ga₂O gas as a group III element oxide gas. The produced Ga₂O gas is discharged from raw material reaction room 101 to raw material chamber 100 via group III element oxide gas discharge port 107. The discharged Ga₂O gas is mixed with the first carrier gas supplied from first carrier gas supply port 102 to raw material chamber 100 and is supplied to gas discharge port 108.

In the first exemplary embodiment, first heater 106 heats raw material chamber 100. When raw material chamber 100 is heated, the temperature of raw material chamber 100 is preferably more than or equal to 800° C., which is higher than the boiling point of the Ga₂O gas. The temperature of raw material chamber 100 is preferably lower than the temperature of growth chamber 111. As described later, when second heater 115 heats growth chamber 111, the temperature of raw material chamber 100 is preferably less than 1800° C., for example. Starting group III element source 105 is placed in raw material boat 104 disposed in raw material reaction room 101. Raw material boat 104 preferably has a shape capable of increasing the contact area between the reactive gas and starting group III element source 105. Raw material boat 104 preferably has a multi-stage dish shape to prevent starting group III element source 105 and the reactive gas from passing through raw material reaction room 101 in a non-contact state, for example.

Methods for producing the group III element oxide gas are roughly classified into a method for reducing starting group III element source 105 and a method for oxidizing starting group III element source 105.

For example, in the reduction method, an oxide (for example, Ga₂O₃) is used as starting group III element source 105, and a reducing gas (for example, H₂ gas, CO gas, CH₄ gas, C₂H₆ gas, H₂S gas, or SO₂ gas) is used as the reactive gas.

In the oxidation method, a non-oxide (for example, liquid Ga) is used as starting group III element source 105, and an oxidizing gas (for example, H₂O gas, O₂ gas, CO gas, NO gas, N₂O gas, NO₂ gas, or N₂O₄ gas) is used as the reactive gas.

As starting group III element source 105, an In source or an Al source may be used in addition to the Ga source. As the first carrier gas, an inert gas, H₂ gas, or the like may be used.

### <Group III Element Oxide Gas Supply Step>

In the group III element oxide gas supply step, the Ga₂O gas generated in the group III element oxide gas generation step is supplied to growth chamber 111 via gas discharge port 108, connection pipe 109, and gas supply port 118. When the temperature of connection pipe 109 connecting raw material chamber 100 and growth chamber 111 is lower than the temperature of raw material chamber 100, a reverse reaction of the reaction for generating the group III element oxide gas occurs, and starting group III element source 105 may deposit in connection pipe 109. Thus, connection pipe 109 is preferably heated by third heater 110 to have a temperature not lower than the temperature of raw material chamber 100.

### <Nitrogen Element-Containing Gas Supply Step>

In the nitrogen element-containing gas supply step, a nitrogen element-containing gas is supplied from nitrogen element-containing gas supply port 113 to growth chamber 111. Examples of the nitrogen element-containing gas include NH₃ gas, NO gas, NO₂ gas, N₂O gas, N₂O₄ gas, N₂H₂ gas, N₂H₄ gas, and HCN gas.

### <Group III Nitride Crystal Generation Step>

In the group III nitride crystal generation step, the raw material gas supplied into growth chamber 111 through each supply step is caused to react to grow a group III nitride crystal on seed substrate 116. Second heater 115 preferably heats growth chamber 111 to a temperature at which the group III element oxide gas and the nitrogen element-containing gas react with each other. At this time, to prevent the occurrence of a reverse reaction of the reaction for generating the group III element oxide gas, it is preferable to control the temperature of growth chamber 111 so that the temperature of growth chamber 111 does not become lower than the temperature of raw material chamber 100 and the temperature of connection pipe 109. The temperature of growth chamber 111 heated by second heater 115 is preferably from 1000° C. to 1800° C., inclusive.

Mixing the group III element oxide gas supplied to growth chamber 111 through the group III element oxide supply step and the nitrogen element-containing gas supplied to growth chamber 111 through the nitrogen element-containing gas supply step upstream of seed substrate 116 allows a group III nitride crystal to grow on seed substrate 116.

Examples of seed substrate 116 include gallium nitride, gallium arsenide, silicon, sapphire, silicon carbide, zinc oxide, gallium oxide, and ScAlMgO₄.

As the second carrier gas, an inert gas, H₂ gas, or the like may be used.

### <Residual Gas High-Temperature-Keeping Discharge Step>

In the residual gas high-temperature-keeping discharge step, unreacted group III element oxide gas and nitrogen element-containing gas, and the first carrier gas, the second carrier gas, and the third carrier gas are discharged from first exhaust pipe 119. At this time, the temperature of first exhaust pipe 119 is preferably kept at a temperature of more than or equal to 1000° C. to suppress deposition from the group III element oxide gas. The deposition reaction of the group III element oxide gas is mainly two reactions represented by Formula (III) and Formula (IV) described above. The temperature of first exhaust pipe 119 can be maintained at a temperature of more than or equal to 1000° C. by extending the length of second heater 115 to the downstream side. First exhaust pipe 119 may independently include a heater to adjust the temperature.

In the residual gas high-temperature-keeping discharge step, group III nitride gas that did not contribute to the crystal growth may be discharged, and the gas may deposit as a group III nitride on the downstream side of first exhaust pipe 119.

In FIG. 1, two exhaust pipes extending downstream from first exhaust pipe 119 are illustrated, but the exhaust pipe is not limited to this configuration. For example, one pipe may be provided. Alternatively, four pipes may be provided. They may be provided line- symmetrically or point-symmetrically.

### <First Deposition Step>

In the first deposition step, the temperature of first deposition pipe 120 is preferably from 700° C. to 1050° C. inclusive, and more preferably from 800° C. to 1000° C. inclusive from the viewpoint of causing the reaction of Formula (III). The temperature control to the above temperature range may be performed, for example, by cooling with cooling water. The cooling may be performed by, for example, lengthening the pipe without using the cooling water. Further, the temperature control may be performed by providing cooling water and a heater. Here, the deposit generated by the reaction of Formula (III) is Ga₂O₃ when the group III element is Ga, and the deposit becomes a film-like accumulated material. Thus, from the viewpoint of preventing breakage of first deposition pipe 120 and improving repair and maintenance, the inner wall of first deposition pipe 120 is preferably covered with a protective pipe (not illustrated) capable of peeling off the deposit. Here, the material of the protective pipe is made of pyrolytic graphite (PG), pyrolytic boron nitride (PBN), carbon (C), SiC, transition metal (Mo, W, etc.), quartz, or the like, from the viewpoint of peeling the deposit. The pipe diameter of the first deposition pipe is preferably more than or equal to 66 mm from the viewpoint of enabling growth of a thickness of 5 mm. Further, the thickness is preferably more than or equal to 72 mm, more preferably more than or equal to 78 mm.

The protective pipe may extend upstream and/or downstream of first deposition pipe 120. For example, the protective pipe may enter first exhaust pipe 119. The protective pipe may enter second deposition pipe 121. The inner diameter of the protective pipe may be more than or equal to 66 mm.

### <Second Deposition Step>

In the second deposition step, the temperature of second deposition pipe 121 is preferably lower than 800° C. from the viewpoint of causing the reaction of Formula (IV). The temperature control to the above temperature range may be performed, for example, by cooling with cooling water. The cooling may be performed by, for example, lengthening the pipe without using the cooling water. Further, the temperature control may be performed by providing cooling water and a heater. Here, the deposit generated by the reaction of Formula (IV) is Ga₂O when the group III element is Ga, and the deposit becomes a powdery accumulated material. Thus, second deposition pipe 121 preferably includes a powder trap filter (not illustrated) from the viewpoint of preventing accumulation of powder at an unintended place. Providing the powder trap filter makes it possible for the powder to accumulate at a desired position, and unexpected clogging of the exhaust pipe can be suppressed by periodically replacing or maintaining the powder trap. Here, a pressure regulating valve and a dry pump are provided downstream of second exhaust pipe 122. Thus, it is also useful from the viewpoint of preventing failure of the pressure regulating valve and the dry pump. The roughness of the powder trap filter is preferably less than or equal to 100 μm, more preferably less than or equal to 50 μm, and still more preferably less than or equal to 10 um from the viewpoint of preventing the powder from flowing downstream of the powder trap filter.

### <Residual Gas Discharge Step>

In the residual gas discharge step, unreacted nitrogen element-containing gas, and the first carrier gas, the second carrier gas, and the third carrier gas are discharged from second exhaust pipe 122.

Maintainability has thus improved. The operation rate can also be improved.

### Second Exemplary Embodiment

### <Group III Nitride Crystal Manufacturing Apparatus>

FIG. 3 is a schematic sectional view illustrating a sectional structure of a group III nitride crystal manufacturing apparatus according to a second exemplary embodiment. The group III nitride crystal manufacturing apparatus according to the second exemplary embodiment is different in including decomposition accelerator 123 that decomposes and inactivates the remaining unreacted nitrogen element-containing gas after the group III nitride crystal generation step.

### <Decomposition Accelerator>

Decomposition accelerator 123 is disposed between seed substrate 116 and first exhaust pipe 119.

The material of decomposition accelerator 123 preferably contains an active metal from the viewpoint of the catalytic effect of the decomposition reaction of the nitrogen element-containing gas. In addition, since the inside of growth chamber 111 is in a high temperature environment of about 1200° C., it is necessary that the material constituting the decomposition accelerator 123 is not melted at the above temperature. Specifically, decomposition accelerator 123 preferably contains at least one element selected from the group consisting of Mo, Ni, Fe, Co, Ti, Cr, Zr, Ta, W, and Pt. In particular, since Mo, Ta, W, Zr, Cr, and Pt have a melting point of more than or equal to 1700° C., deterioration due to softening and alloying with Ga hardly occur, and the possibility of reacting with the reactive gas is lower even when growth chamber 111 is heated using second heater 115. Thus, decomposition accelerator 123 more preferably contains at least one element of Mo, Ta, Zr, Cr, and Pt.

From the viewpoint of promoting the decomposition of the nitrogen element- containing gas, it is preferable that decomposition accelerator 123 further increases the surface area and improves the percentage of surface contact with the nitrogen element-containing gas. For example, when one metal plate is used as decomposition accelerator 123, the surface area of decomposition accelerator 123 is the total area of the front and back surfaces. From the viewpoint of improving the decomposition rate, the total surface area of decomposition accelerator 123 preferably has a normalized surface area of more than or equal to 5 when the reactor sectional area of growth chamber 111 is normalized to 1, more preferably has a normalized surface area of more than or equal to 16.5, and particularly preferably has a normalized surface area of more than or equal to 32. To increase the surface area of decomposition accelerator 123, a punching plate-shaped multilayer body or a porous body may be used. In the multilayer body, for example, a plurality of metal plates are disposed at intervals with spacers. As decomposition accelerator 123, sponge-like metal such as sponge-like iron may be used. Further, decomposition accelerator 123 may be a support in which fine particles of Pt or the like are supported on the inner surface of a metal or ceramic having a honeycomb structure. This causes the nitrogen element-containing gas to be decomposed at the downstream portion of substrate susceptor 117, which can more efficiently suppress parasitic growth of the group III nitride crystal.

The shape of decomposition accelerator 123 may be any shape that does not disturb the discharge of the gas from first exhaust pipe 119. Decomposition accelerator 123 may have, for example, a plate shape or an annular shape.

From the viewpoint of promoting the decomposition of the nitrogen element-containing gas, it is preferable that decomposition accelerator 123 is installed in a region where the temperature of the downstream portion of substrate susceptor is more than or equal to 800° C.

### <Method for Producing Group III Nitride Crystal>

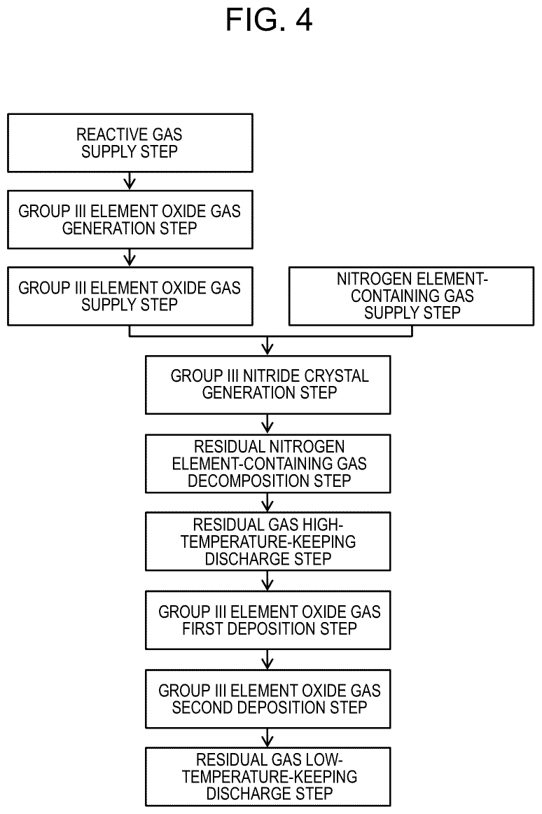

FIG. 4 is a flowchart illustrating a method for producing a group III nitride crystal according to a second exemplary embodiment.

The method for producing a group III nitride crystal according to the second exemplary is different from the method for producing a group III nitride crystal according to the first exemplary embodiment in including a residual nitrogen element-containing gas decomposition step.

Hereinafter, the residual nitrogen element-containing gas decomposition step as a difference from the first exemplary embodiment will be described.

### <Residual Nitrogen Element-Containing Gas Decomposition Step>

In the residual nitrogen element-containing gas decomposition step, the nitrogen element-containing gas not consumed in the group III nitride crystal generation step is inactivated by decomposition accelerator 123. Decomposition accelerator 123 is disposed downstream of seed substrate 116, that is, downstream of substrate susceptor 117 holding seed substrate 116 so as not to inhibit the growth of the group III nitride crystal on seed substrate 116. In other words, decomposition accelerator 123 is disposed between substrate susceptor 117 and first exhaust pipe 119. Decomposing and deactivating the nitrogen element-containing gas in decomposition accelerator 123 makes it possible to suppress the reaction between the nitrogen element-containing gas not used for the generation of the group III nitride crystal and the group III element oxide gas in the downstream portion of seed substrate 116, and to prevent the parasitic growth of the group III nitride crystal on the reactor wall and the exhaust pipe. Reducing parasitic growth of the group III nitride crystal on the reactor wall and the exhaust pipe makes it possible to perform highly reliable production and to suppress maintenance cost. Further, the crystal quality is improved by reducing particles due to parasitic growth.

For example, when the group III nitride crystal is gallium nitride, and NH₃ gas is used as the nitrogen element-containing gas, the decomposition reaction of the nitrogen element-containing gas is represented by Formula (III) shown below.

2NH₃(g)→N₂(g)+3H₂(g) (III)

### OVERVIEW OF EXAMPLES AND COMPARATIVE EXAMPLES

A group III nitride crystal was grown using the growth furnace illustrated in FIG. 1. Here, GaN was grown as the group III nitride crystal. A liquid Ga was used as the starting Ga source, Ga was caused to react with H₂O gas as the reactive gas, and Ga₂O gas was used as the group III element oxide gas. NH₃ gas was used as the nitrogen element-containing gas, and a mixture of H₂ gas and N₂ gas was used as the first carrier gas and the second carrier gas. As the seed substrate, a two-inch GaN self-standing substrate was used. An experiment was performed to obtain a GaN crystal having a thickness of 5 mm by one growth. The growth of GaN crystal was repeated under the above conditions, and the number of times of operations operable until the pipe is clogged and the pressure regulating valve or the dry pump fails due to the powder volume was compared.

### Example 1

The inlet temperature of the first exhaust pipe was 1050° C., the outlet temperature was 1020° C., the inlet temperature of the first deposition pipe was 1020° C., the outlet temperature was 780° C., the inlet temperature of the second deposition pipe was 780° C., the outlet temperature was 50° C., the inlet temperature of the second exhaust pipe was 50° C., and the outlet temperature was the atmospheric temperature. A protective pipe was installed on the inner wall of the first deposition pipe, and a powder trap filter was installed on the second deposition pipe. The protective pipe of the first deposition pipe was replaced with one to which no deposit was attached for each run. The pipe diameter of the protective pipe was 90 mm, and the roughness of the powder trap filter was less than or equal to 10 μm.

As a result of repeatedly performing the 5 mm thickness growth, the exhaust pipe was not clogged and the pressure regulating valve and the dry pump did not fail even after performing 30 runs. Thus, using the configuration of the present example makes it possible to perform more than or equal to 30 runs of 5 mm thickness GaN crystal growth.

### Reference Example 1

The inlet temperature of the first exhaust pipe was 1050° C., the outlet temperature was 1020° C., the inlet temperature of the first deposition pipe was 1020° C., the outlet temperature was 780° C., the inlet temperature of the second deposition pipe was 780° C., the outlet temperature was 50° C., the inlet temperature of the second exhaust pipe was 50° C., and the outlet temperature was the atmospheric temperature. A protective pipe was not installed on the inner wall of the first deposition pipe, but a powder trap filter was installed on the second deposition pipe. The roughness of the powder trap filter was less than or equal to 10 μm.

As a result of repeatedly performing 5 mm thickness growth, the growth thickness of the second run stopped at 4.3 mm. This is because the inner wall of the first deposition pipe was clogged by an adhering substance in the middle of the second run, and the appropriate gas flow was disturbed. Thus, using the configuration of the present example makes it possible to perform 1 run of 5 mm thickness GaN crystal growth.

### Reference Example 2

The inlet temperature of the first exhaust pipe was 1050° C., the outlet temperature was 1020° C., the inlet temperature of the first deposition pipe was 1020° C., the outlet temperature was 780° C., the inlet temperature of the second deposition pipe was 780° C., the outlet temperature was 50° C., the inlet temperature of the second exhaust pipe was 50° C., and the outlet temperature was the atmospheric temperature. A protective pipe was installed on the inner wall of the first deposition pipe, but a powder trap filter was not installed on the second deposition pipe. The protective pipe of the first deposition pipe was replaced with one to which no deposit was attached for each run. The pipe diameter of the protective pipe was 90 mm.

As a result of repeatedly performing 5 mm thickness growth, when the growth thickness of the third run reached 1.9 mm, the dry pump became in a state of motor overload due to accumulation of powder, and normal pressure adjustment became impossible. Thus, using the configuration of the present example makes it possible to perform 2 runs of 5 mm thickness GaN crystal growth. A large amount of accumulation of an adhering substance was also confirmed in the pressure regulating valve.

### Comparative Example 1

The inlet temperature of the first exhaust pipe was 900° C., the outlet temperature was 800° C., the inlet temperature of the first deposition pipe was 800° C., the outlet temperature was 300° C., the inlet temperature of the second deposition pipe was 300° C., the outlet temperature was 50° C., the inlet temperature of the second exhaust pipe was 50° C., and the outlet temperature was the atmospheric temperature. A protective pipe was not installed on the inner wall of the first deposition pipe, and a powder trap filter was not installed on the second deposition pipe.

As a result of performing 5 mm thickness growth, the growth thickness of the first run stopped at 4.6 mm. This is because the inner wall of the first deposition pipe was clogged by an adhering substance in the middle of the first run, and the appropriate gas flow was disturbed. Thus, with the configuration of the present example, it is not possible to perform 5 mm thickness GaN crystal growth even for 1 run.

The crystal growth apparatus used in the present Examples, Reference Examples, and Comparative Examples are of a single wafer type, and can produce crystals having a diameter of up to 6 inches. Even when 6-inch crystal production is performed, similar results can be obtained by satisfying the above conditions.

### Industrial Applicability

According to the group III nitride crystal manufacturing apparatus and manufacturing method according to the present disclosure, by providing the first deposition pipe and the second deposition pipe with controlled temperature downstream of the first exhaust pipe, clogging of the exhaust pipe can be suppressed, and a high-quality group III nitride crystal can be produced with high productivity.

### REFERENCE MARKS IN THE DRAWINGS

100 raw material chamber
101 raw material reaction room
102 first carrier gas supply port
103 reactive gas supply pipe
104 raw material boat
105 starting group III element source (starting Ga source)
106 first heater
107 group III element oxide gas discharge port
108 gas discharge port
109 connection pipe
110 third heater
111 growth chamber
112 third carrier gas supply port
113 nitrogen element-containing gas supply port
114 second carrier gas supply port
115 second heater
116 seed substrate
117 substrate susceptor
118 gas supply port
119 first exhaust pipe
120 first deposition pipe
121 second deposition pipe
122 second exhaust pipe
123 decomposition accelerator

1. A group III nitride crystal manufacturing apparatus comprising:
a raw material chamber that generates a group III element oxide gas;
a growth chamber that causes the group III element oxide gas supplied from the raw material chamber to react with a nitrogen element-containing gas to generate a group III nitride crystal on a seed substrate;
a first exhaust pipe that is connected downstream of the growth chamber, discharges gas from the growth chamber, and is set to more than or equal to 1000° C.;
a first deposition pipe connected to a downstream side of the first exhaust pipe and set to more than or equal to 700° C. and less than or equal to 1050° C.;
a second deposition pipe connected to a downstream side of the first deposition pipe and set to less than 800° C.; and
a second exhaust pipe that is connected to a downstream side of the second deposition pipe and exhausts gas to an outside.

2. The group III nitride crystal manufacturing apparatus according to claim 1, the apparatus having a temperature set to decrease in an order of the first exhaust pipe, the first deposition pipe, and the second deposition pipe.

3. The group III nitride crystal manufacturing apparatus according to claim 1, the apparatus comprising a protective pipe provided on an inner wall of the first deposition pipe.

4. The group III nitride crystal manufacturing apparatus according to claim 3, wherein the protective pipe contains at least one material selected from the group consisting of pyrolytic graphite (PG), pyrolytic boron nitride (PBN), carbon (C), silicon carbide (SiC), transition metal, and quartz.

5. The group III nitride crystal manufacturing apparatus according to claim 3, wherein the protective pipe has an inner diameter of more than or equal to 66 mm.

6. The group III nitride crystal manufacturing apparatus according to claim 1, wherein the second deposition pipe includes a powder trap filter.

7. The group III nitride crystal manufacturing apparatus according to claim 6, wherein the powder trap filter has a filter roughness of less than or equal to 100 μm.

8. A method for producing a group III nitride crystal, the method comprising:
causing a group III element source to react with a reactive gas to produce a group III element oxide gas;
causing the group III element oxide gas to react with a nitrogen element-containing gas to generate a group III nitride crystal on a seed substrate; and
causing a film-like deposit to deposit at a temperature of more than or equal to 700° C. and less than or equal to 1050° C. and then causing a powdery deposit to deposit at a temperature of less than 800° C. with respect to exhaust of unreacted group III element oxide gas of more than or equal to 1000° C. to be exhausted.

9. The method for producing a group III nitride crystal according to claim 8, wherein the exhaust of the group III element oxide gas is exhausted to an outside via a first exhaust pipe having a temperature of more than or equal to 1000° C., a first deposition pipe having a temperature of more than or equal to 700° C. and less than or equal to 1050° C., a second deposition pipe having a temperature of less than 800° C., and a second exhaust pipe.

10. The method for producing a group III nitride crystal according to claim 9, wherein a temperature is caused to decrease in an order of the first exhaust pipe, the first deposition pipe, and the second deposition pipe.

11. The method for producing a group III nitride crystal according to claim 9, the method further comprising decomposing a part of the nitrogen element-containing gas that has not reacted between the seed substrate and the first exhaust pipe.
